(19) United States
(12) Patent Application Publication
(10) Pub. No.: US 2011/0169489 A1
(43) Pub. Date: Jul. 14, 2011

(54) RF COIL DOCKING STATION FOR MAGNETIC RESONANCE SYSTEMS

(75) Inventor: Christoph Leussler, Hamburg (DE)

(73) Assignee: KONINKLIJKE PHILIPS ELECTRONICS N.V., Eindhoven (NL)

(21) Appl. No.: 13/119,453

(22) PCT Filed: Sep. 17, 2009
(86) PCT No.: PCT/IB09/54063

§ 371 Date: Mar. 17, 2011

(30) Foreign Application Priority Data
Sep. 23, 2008 (EP) 08164885.9

(51) Int. Cl. G01R 33/44; G06F 9/445; G01K 1/00

(52) U.S. Cl. 324/307; 717/177; 374/100; 324/318; 340/10.1; 374/E01.001

(57) ABSTRACT

An RF coil docking station (30) comprises: an RF coil receptacle (32, 34, 36, 38) configured to receive and store an RF coil (20, 22, 24) and to convey data between the RF coil docking station and the stored RF coil (22, 24); and a processor (46, 54) configured to control conveyance of data between the RF coil docking station and the stored RF coil to modify an operational state of the stored RF coil. In some embodiments, the RF coil docking station (30) comprises a plurality of RF coil receptacles (32, 34, 36, 38) configured to receive and store RF coils and to identify the stored RF coils, the processor is configured to select one or more of the stored RF coils for performing an identified magnetic resonance procedure (90), and an indicator (52, 55) is configured to indicate the selected one or more of the stored RF coils.

### FIELD OF THE INVENTION

The following relates to the magnetic resonance and related arts.

### BACKGROUND OF THE INVENTION

Magnetic resonance (MR) scanners and systems are employing increasingly sophisticated coils and coil array assemblies. Coils are designed for highly specific applications, such as brain imaging, joint (e.g., knee or elbow) imaging, various types of chest or torso imaging, and so forth. Pre-formed coil array assemblies are designed to be optimized for SENSE imaging or other parallel imaging techniques applied to specific anatomical regions. On the other hand, some parallel imaging applications may be better performed using a plurality of suitably placed individual receive coil loops. Some coils include transmit capability, while others are receive-only coils and rely upon a whole-body transmit coil integral with the MR scanner, or upon another transmit coil, in order to perform a complete magnetic resonance sequence. Different coils may have different capacitance or impedance characteristics that affect compatibility of the coil with various available RF electronic components or RF receive chains.

Different power inputs are used in different coils, such as wireless or wired power input, or no power input at all in the MR scanner (e.g., relying upon an on-board battery or capacitor to power the coil). Different data communication pathways are used in different coils, such as wired, wireless, and/or optical data communication pathways. There is also a drive toward providing on-board “intelligence” for coils or coil array assemblies, enabling the coil or coil array to have individual coil elements switched on or off or variously coupled together, providing precise tuning of the resonance frequency, or so forth. In wireless coils, on-board electronics may perform analog-to-digital data conversion so that the wireless transmission is digital, which is generally less susceptible to noise or interference. Different data transmission protocols may also be provided, with on-board electronics enabling selection of the data communication mode for cross-compatibility with different RF receive systems.

One consequence of these developments is that the selection and maintenance of RF coils is becoming increasingly complex. As the number of available coils in a typical MR scanner facility increases, it becomes increasingly difficult to identify the best coil, coil pre-formed coil assembly, or set of individual coils, for a particular imaging session or task. Such identification entails visually recognizing the “right” coil or coils; verifying that the selected coils are adequately electrically charged (in the case of battery-powered wireless coils) or can be powered; verifying that the selected coils have the right wired, wireless, or optical data communication connectors; possibly performing coil configuration operations such as resonance frequency tuning or ensuring that such configuration parameters are already properly set; and so forth.

In existing MR facilities, these coil selection and configuration tasks are typically supported by coil labeling and implementation of workflow procedures. For example, coils may be labeled with visually perceptible printed text and/or graphics as to identify key features such as the anatomical region the coil is intended to image, the number of coil elements in the case of a pre-formed coil array assembly, or so forth. Some limited on-board diagnostics may also be provided, such as an LED indicator that shows whether the battery is charged. However, bore space limitations and the need for compatibility with high magnetic fields used in MR tend to limit the amount of on-board diagnostics that manufacturers are willing to incorporate into RF coils. Workflow procedures include commonsense provisions such as storing the RF coils in a designated location with each coil stored in a designated slot, cubbyhole or other storage receptacle or station, providing coil-compatible battery chargers at the storage receptacle or station of each wireless battery-powered RF coil, providing a wall chart or other visually perceptible aid identifying the preferred coils for various MR applications, and so forth.

These existing techniques have numerous deficiencies. The amount of information that can be included on coil labels is limited by the amount of label-compatible surface space available on the coil, as well as by aesthetic considerations. LED indicators or other on-board diagnostics can be problematic in the MR environment, and can increase the coil size which is disadvantageous due to bore space limitations. Workflow procedures are reliant upon human compliance which may be less than exemplary, and also tend to rely upon manual updates (for example of a wall chart identifying preferred coils for various MR procedures) that may be performed infrequently or not at all. Further, these existing techniques do not take advantage of the increasing use of on-board coil “intelligence” to assist in coil maintenance.

The following provides new and improved apparatuses and methods which overcome the above-referenced problems and others.

### SUMMARY OF THE INVENTION

In accordance with one disclosed aspect, an RF coil docking station comprises: an RF coil receptacle configured to receive and store an RF coil and to convey data between the RF coil docking station and the stored RF coil; and a processor configured to control conveyance of data between the RF coil docking station and the stored RF coil to modify an operational state of the stored RF coil.

In accordance with another disclosed aspect, an RF coil docking method comprises: storing an RF coil; and during the storing, modifying an operational state of the stored RF coil.

In accordance with another disclosed aspect, an RF coil docking station comprises: a plurality of RF coil receptacles configured to receive and store RF coils and to identify the stored RF coils; and a processor configured to select one or more of the stored RF coils for performing an identified magnetic resonance procedure; and an indicator configured to indicate the selected one or more of the stored RF coils.

One advantage resides in more efficient, precise, and accurate coil selection.

Another advantage resides in providing more up-to-date coil configurations.

Another advantage resides in increased coil “up-time”.

Further advantages will be apparent to those of ordinary skill in the art upon reading and understand the following detailed description.

### BRIEF DESCRIPTION OF THE DRAWINGS

The invention may take form in various components and arrangements of components, and in various steps and arrangements of steps. The drawings are only for purposes of illustrating the preferred embodiments and are not to be construed as limiting the invention.

FIG. 1 diagrammatically shows a perspective view of a magnetic resonance system including an RF coil docking station.

FIG. 2 diagrammatically shows selected operational components and data memories or logical storage units of the RF coil docking station of FIG. 1.

Corresponding reference numerals when used in the various figures represent corresponding elements in the figures.

### DETAILED DESCRIPTION OF EMBODIMENTS

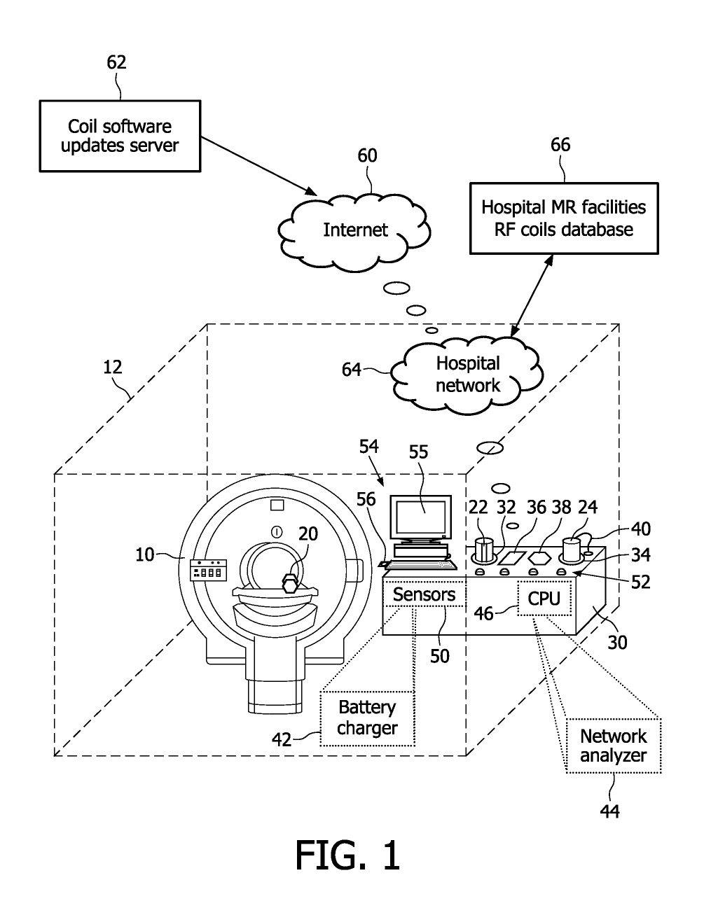

With reference to FIG. 1, a magnetic resonance system includes a magnetic resonance scanner 10 disposed in a shielded room 12 that provides at least some radio frequency isolation between the magnetic resonance scanner 10 and the environment outside of the shielded room 12. The magnetic resonance scanner 10 can be substantially any type of magnetic resonance scanner, including the illustrated closed horizontal bore-type scanner, an open-bore scanner, a vertical magnetic resonance scanner, or so forth. As some illustrative examples, some suitable embodiments of the magnetic resonance scanner 10 include the Achieva™ or Intera™ closed horizontal-bore scanners or the Panorama™ open-bore scanners, each of which is available from Koninklijke Philips Electronics N.V. (Eindhoven, the Netherlands). The magnetic resonance scanner 10 is to be understood as including any peripheral components that may not be illustrated but that may be suitably employed in the performance of magnetic resonance imaging, magnetic resonance spectroscopy, or other magnetic resonance procedures. Such peripheral components may include, for example: a reconstruction processor for reconstructing acquired magnetic resonance imaging data into an image based on a priori knowledge of the spatial encoding employed during imaging data acquisition; a main magnet power supply; cryogenic components for maintaining a superconducting main magnet (if used) at a temperature below the superconducting critical temperature; magnetic field gradient amplifiers; graphical displays for presenting acquired magnetic resonance images or spectra; and so forth. The magnetic resonance system of FIG. 1 also includes a plurality of radio frequency (RF) coils. These coils optionally include a whole-body RF coil (not shown) disposed in the scanner 10, and one or more local RF coils 20, 22, 24 that are configured for various imaging tasks such as brain imaging, joint imaging, chest or torso imaging, SENSE imaging, or so forth. As used herein, the term “RF coil” is intended to encompass singular RF coils as well as pre-formed coil array assemblies. For example, a pre-formed 16-element SENSE coil array is referred to herein as a single RF coil. Alternatively, one could construct a 16-element SENSE coil array by suitable arrangement of 16 separately packaged RF coils.

In general, the RF coils 20, 22, 24 are selectively loaded into the magnetic resonance scanner 10 when intended for use in a magnetic resonance procedure, as shown for the RF coil 20 positioned for loading into the bore of the scanner 10, and are selectively unloaded or removed from the magnetic resonance scanner 10 when the RF coil 22, 24 is not intended for use in the magnetic resonance procedure. In some circumstances, an RF coil not intended for use in the magnetic resonance procedure may nonetheless be left loaded in the scanner 10 (situation not illustrated). However, typically those RF coils that are not used or intended for use in the magnetic resonance procedure are stored in or at an RF coil docking station 30, as is the case for illustrated RF coils 22, 24. More particularly, the RF coil 22 is stored in an RF coil receptacle 32 that is configured to receive the RF coil 22, while the RF coil 24 is stored in an RF coil receptacle 34 that is configured to receive the RF coil 24. The illustrated RF coil docking station 30 includes two additional RF coil receptacles 36, 38 that are not occupied in the depiction of FIG. 1.

Each RF coil receptacle 32, 34, 36, 38 is configured to receive and store an RF coil. The illustrated RF coil receptacles 32, 34, 36, 38 store the corresponding RF coils partially open to view, which advantageously enables the magnetic resonance system operator to readily see which RF coils are currently in storage. Alternatively, the RF coil receptacles, or a portion thereof, may store their respective RF coils in a wholly enclosed space, such as in a drawer or covered cubbyhole.

Each RF coil receptacle 32, 34, 36, 38 is further configured to convey data from the RF coil docking station 30 to the stored RF coil 22, 24. This configuration can include or entail a wireless data communication connection, an electrically conductive data communication connection, an optical fiber data communication connection, or so forth. For example, the RF coil 24 includes a cable 40, which may be either an optical fiber cable or an electrically conductive data communication connection (single wire or multiwire). The cable 40 connects with the RF coil docking station 30 to convey data from the RF coil docking station 30 to the stored RF coil 24. On the other hand, the RF coil 22 does not include a visible cable, and the connection for conveying data from the RF coil docking station 30 to the stored RF coil 22 is either a wireless connection or a wired socket within the RF coil receptacle 32 that automatically connects with the RF coil 22 when the latter is received into and stored in the RF coil receptacle 32. In some embodiments, the RF coil receptacle is configured to convey data from the RF coil docking station 30 to the stored RF coil 22, 24 via a same (wired or wireless) connection of the stored RF coil that is used to connect the stored RF coil when not stored with the magnetic resonance scanner 10. In other embodiments, a different (wired or wireless) connection is used. In some embodiments, the cable 40 may also include an electrical power conduction path. For example, the cable 40 may also be used to electrically recharge a battery (not shown) of the RF coil 24.

The RF coil docking station 30 does not merely provide storage for the stored RF coils 22, 24; rather, it also provides maintenance for the stored RF coils 22, 24. For example, in some embodiments the RF coil docking station 30 includes a battery charger 42 for charging an on-board battery or power storage capacitor (if any) of the stored RF coil. A network analyzer 44 is optionally included in or with the RF coil docking station 30 to measure a resonance center frequency, resonance Q factor, or other radio frequency resonance characteristic of the stored RF coil 22, 24, and a central processing unit (CPU) 46 or other processor of the RF coil docking station 30 control conveyance of data from the RF coil docking station 30 to the stored RF coil 22, 24 to adjust the measured radio frequency resonance characteristic of the stored RF coil to a desired radio frequency resonance characteristic value. For example, when storage of an RF coil is identified, the processor 46 suitably causes the network analyzer 44 to measure the resonance frequency of the RF coil. If it differs from the magnetic resonance frequency or another desired resonance frequency, then the processor 46 suitably causes a capacitance or other resonance frequency-impacting parameters of the RF coil to be adjusted to adjust the measured resonance frequency of the stored RF coil to a desired magnetic resonance frequency value. If the RF coil is a “smart” coil that includes an on-board processor capable of adjusting the resonance frequency, then the processor 46 suitably causes conveyance of data from the RF coil docking station 30 to the stored RF coil 22, 24 to adjust the measured resonance frequency. For an analog RF coil having an analog tuning input, the processor 46 provides a suitable voltage input or other analog input to the analog tuning input of the analog RF coil to adjust the measured resonance frequency.

In some embodiments, one or more sensors 50 of the RF coil docking station 30 sense or detect selected characteristics of the stored RF coils 22, 24 including at least the identity of the stored RF coils 22, 24. The detection of identity of the stored RF coil can be a simple sensing or detection of whether the RF coil receptacle 32, 34 is occupied or whether the RF coil receptacle 36, 38 is unoccupied. In the former case, if the coil receptacles 32, 34, 36, 38 are geometrically keyed or otherwise configured to ensure that only one type of RF coil can be received by a given one of the coil receptacles 32, 34, 36, 38, then the sensing or detection of the RF coil receptacle 32, 34 being occupied automatically identifies the type of the stored RF coils 22, 24. On the other hand, if two or more different RF coil types can be loaded into the same RF coil receptacle, then additional information must be conveyed to the RF coil docking station 30 to identify the stored RF coils 22, 24. This additional information may take the form of (for example): an impedance of the wired connection 40 for conveying data from the RF coil docking station 30 to the stored RF coil 24; digital coil identification data conveyed from the stored RF coil to the RF coil docking station 30 (an approach suitable when the RF coil has on-board “intelligence” in the form of an on-board digital processor, controller, or the like that can access and cause conveyance of stored coil identification data); a mechanical coil-type sensor (for example, depending upon the type of the stored RF coil, different sensor buttons or button combinations may be activated); or so forth.

The one or more sensors 50 may include other types of sensors, such as temperature sensors, configuration sensors (for example, to detect the configuration of a multi-element preformed coil array), and so forth. Additionally, a set of LEDs 52 or other user-perceptible outputs are optionally provided to identify which of the stored RF coils are in condition for use in a magnetic resonance procedure.

In some embodiments, the RF coil docking station 30 assists the human magnetic resonance system operator by selecting coils suitable for use in a given magnetic resonance procedure. For example, a human user may operate a computer 54 to select a magnetic resonance procedure, such as a brain scan, a chest scan employing SENSE, or so forth. An appropriate RF coil or plurality of RF coils is chosen for performing the selected magnetic resonance procedure based on processing performed by a processor of the RF coil docking station 30, such as the CPU 46 or the processor of the computer 54, and further based on knowledge of the identity of the stored RF coils provided by the RF coil docking station 30. The chosen RF coil or coils is suitably indicated by the LEDs 52 or on a display 55 of the computer 54.

In some embodiments in which the stored RF coil is a “smart” RF coil including a processor or controller and suitable programming stored in an electronically erasable programmable read only memory (EEPROM) or the like, the RF coil docking station 30 conveys data from the RF coil docking station 30 to the stored RF coil 22, 24 to install an RF coil software or firmware update. For example, a software or firmware update may be obtained on an optical disk and loaded into the computer 54 using a suitable optical disk drive 56. Alternatively, a software or firmware update may be obtained via the Internet 60 from a coil software updates server 62. In the illustrated embodiment, the RF coil docking station 30 is in wireless communication with a hospital network 64 acting as a gateway to the Internet 60, thus providing the RF coil docking station 30 access to the coil software updates server 62. Wired network connections can be substituted for one or more of the diagrammatically depicted wireless network connections.

Another benefit of networking the RF coil docking station 30 is that in some embodiments, remotely stored RF coils can be identified. For example, a hospital may include more than one magnetic resonance system, each having a plurality of local RF coils. A hospital magnetic resonance facilities RF coils database 66 suitably communicates with the illustrated RF coil docking station 30 of the illustrated magnetic resonance system, and also communicates with the RF coil docking stations of other magnetic resonance systems in the hospital. The RF coils database 66 contains a current listing of the identities and locations of all stored RF coils. When the human user identifies a magnetic resonance procedure for execution, the RF coil docking station 30 attempts to identify a suitable set of one or more RF coils for use in performing the identified magnetic resonance procedure. However, if one or more needed RF coils are not available, then the RF coil docking station 30 optionally accesses the RF coils database 66 to see if any of the other magnetic resonance systems have a suitable currently stored (and hence not currently in use) RF coil. If so, then this RF coil and its location are identified to the human user via the display 55 of the computer 54.

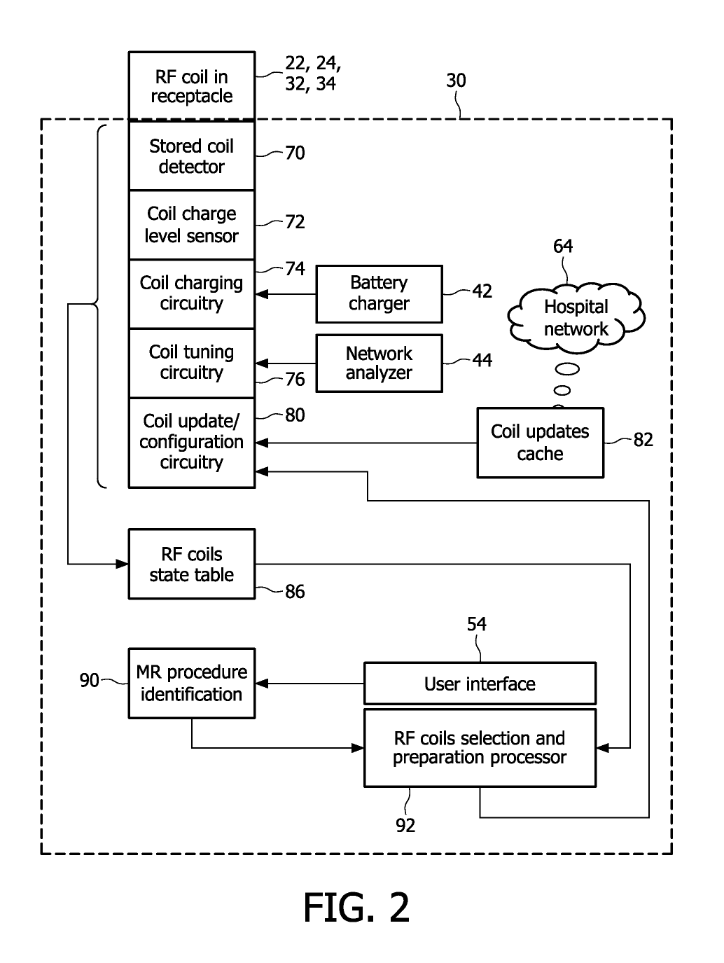

With continuing reference to FIG. 1 and with further reference to FIG. 2, some illustrative embodiments of the RF coil docking station 30 and activities performed by the RF coil docking station 30 are further described. In FIG. 2, the RF coil docking station 30 is embodied in conjunction with the computer 54 which provides the user interface and optionally some or all digital data processing capability of the RF coil docking station 30. More generally, in some embodiments all digital data processing performed by the RF coil docking station 30 is performed by the CPU 46 which is integrally housed in the main housing of the RF coil docking station 30; whereas in other embodiments all digital data processing performed by the RF coil docking station 30 is performed by the processor of the computer 54; whereas in yet other embodiments digital data processing performed by the RF coil docking station 30 is shared or divided between the integral CPU 46 and the processor of the computer 54. As yet a further variation, it is contemplated for the computer 54 to be integrated in the main housing of the RF coil docking station 30, for example by providing the single processor 46 operatively connected with an LCD display (not shown) integrally built into the main housing of the RF coil docking station 30.

One of the RF coils 22, 24 is inserted into its corresponding respective receptacle 32, 34. A stored coil detector 70 detects the insertion of the coil. The coil detector 70 can employ a mechanical sensor such as a push-button that is depressed by the inserted RF coil, a wireless sensor such as an inductive sensor that detects the proximate inductance of the inserted RF coil, an electrical sensor that detects an electrical connection with the inserted RF coil made automatically or by manual attachment of the cable 40, or so forth. Optionally, the processor 46 is configured to control conveyance of data from the RF coil docking station 30 to the stored RF coil 22, 24 to ensure that the stored RF coil assumes an off state, a standby state, or another operational state in which the stored RF coil does not interfere with other RF coils. Optionally, the processor 46 is configured to control conveyance of data from the RF coil docking station to the stored RF coil 22, 24 to perform a usability test of the stored RF coil. The usability test may entail, for example, measuring a resonance frequency of the stored RF coil 22, 24 using the network analyzer 44, invoking on-board diagnostics of the RF coil 22, 24 (assuming the RF coil has on-board processing capability including some self-test capability), or so forth. The sensor or sensors 50 of the RF coil docking station 30 are configured to sense or detect a result of the performed usability test, and the indicator LEDs 52 are suitably lighted to generate a visually perceptible indication of usability of the stored RF coil based on the sensed or detected result of the performed usability test. In some embodiments, for example, each LED indicator 52 includes a red LED and a green LED, with the red LED illuminated to indicate the corresponding RF coil is not currently usable, and the green LED illuminated to indicate that the RF coil is ready for use.

Further, if the inserted RF coil is a wireless coil that includes an on-board battery or storage capacitor, then a coil charge level sensor 72 detects or measures the stored charge of the battery or storage capacitor and, if appropriate, activates coil charging circuitry 74 to operatively connect the battery charger 42 with the inserted RF coil to initiate charging or recharging.

The RF coil docking station 30 optionally performs various other coil maintenance operations. For example, coil tuning circuitry 76 configures the network analyzer 44 to measure a radio frequency resonance characteristic of the stored RF coil, such as the resonance frequency or the resonance full width at half maximum (FWHM) or another “width” measure. If the measured radio frequency resonance characteristic or characteristics are not within acceptable limits, the coil tuning circuitry 76 conveys data from the RF coil docking station 30 to the stored RF coil to adjust the measured radio frequency resonance characteristic of the stored RF coil to a desired radio frequency resonance characteristic value. Instead of measuring the radio frequency characteristic using the network analyzer 44, the value of the radio frequency characteristic is optionally inferred from other information, such as a measured coil temperature, and a resonance characteristic adjustment optionally made based on the inference. The electrical charging or recharging may be via a conductive connection, or via a wireless (e.g., inductive or capacitive) connection. The coil tuning circuitry 76 is considered part of the processor of the RF coil docking station, and may be embodied by the CPU 46, by dedicated analog RF circuitry, by a combination thereof, or so forth.

Another optional maintenance operation is software or firmware updating. Coils with on-board intelligence include software or firmware providing the programming for performing autonomous operations on the coil. Such autonomous operations may include, for example: automatically detuning the RF coil when the load exceeds a selected maximum load; connecting or disconnecting or changing connective configuration of coil elements of a preformed multi-element coil array; adjusting a capacitance or other RF tuning components to change a resonance frequency or resonance FWHM; providing feedback on power level in the case of a wireless battery- or storage capacitor-operated RF coil; performing on-board analog-to-digital signal conversion or other on-board signal processing to condition the received MR signal for porting off the RF coil; or so forth. In such cases, the vendor may occasionally provide a software or firmware update, for example via the hospital network 64 as illustrated, or via an update optical disk (e.g., update CD loaded in the optical disk drive 56), or so forth. The received software or firmware update is stored in a coil updates cache 82. When the coil is detected as being stored at the RF coil docking station 30, then coil update/configuration circuitry 80 checks the updates cache 82 and, if a relevant cached software or firmware update is identified, uploads the cached software or firmware update to the stored RF coil. Optionally, the user is first notified of the available coil software or firmware update via the display 55 of the computer 54 or by another human-perceptible indication, and human approval is required before uploading the cached software or firmware update to the stored RF coil. This optional approval process ensures that the MR operator is aware of the update, which could in some instances affect coil operation in a manner that affects the MR imaging.

Thus, it is seen that the RF coil docking station 30 provides assistance in maintaining the RF coils 20, 22, 24. Additionally, the RF coil docking station 30 provides assistance in using the RF coils, for example by optionally providing the human MR operator with a recommended selection of RF coils for using in a particular MR procedure, and optionally configuring the chosen RF coils for the selected MR procedure.

Toward this end, the RF coil docking station 30 maintains an RF coils state table 86 that provides relevant state information about the RF coils, such as: whether or not they are stored in the RF coil docking station 30; optionally, the availability of RF coils at other nearby MR facilities (recalled, for example, from the hospital MR facilities RF coils database 66 illustrated in FIG. 1); the charge status of wireless coils that rely upon an on-board battery or storage capacitor for operation; more generally, operational status of stored RF coils which may include, for example, indicating whether a coil is currently malfunctioning and hence unavailable; RF coil reliability history (for example, stored as a percent uptime value or so forth); the current resonance frequency of each RF coil; the current configuration of on-board configurable coils such as preformed multi-element coil arrays; and so forth. The state information may also include permanent “state” information about the RF coils, such as: the coil type (e.g., head coil, torso coil, elbow coil, etc.); coil manufacturer information; compatibility information (for example, the format of the signal output—this may be a permanent RF coil characteristic or, in some RF coils with on-board intelligence, this may be an adjustable characteristic); or so forth. Still further, the state information may include annotations or other information added by the MR facility users, such as: designations of certain MR procedures for which a specific RF coil is preferred; designations of certain RF coils as “primary” RF coils to be used preferably over other RF coils designated as “secondary” RF coils; and so forth.

The human MR operator provides an identification of the MR procedure 90 that is to be executed, for example using the computer or another suitable user interface 54. Based on this information and information provided by the RF coils state table 86, an RF coils selection and preparation processor 92 identifies one or more recommended RF coils to the human MR operator. The amount of processing the RF coils selection and preparation processor 92 performs depends upon the specific embodiment. In some embodiments, the RF coils state table 86 stores a list of specific MR procedures for which each RF coil is intended, and the RF coils selection and preparation processor 92 performs a table lookup to identify the RF coil recommendation. In more complex embodiments, the RF coils selection and preparation processor 92 may resolve conflicts, such as two or more operatively equivalent RF coils both indicated as appropriate for the identified MR procedure 90, based on secondary information such as the relative charge levels of the two RF coils (in the case of wireless coils), the optional annotation of RF coils as “primary” or “secondary”, RF coil reliability history (biasing toward recommending the RF coil that has historically been more reliable), or so forth. In some still more complex embodiments, the RF coil recommendation is constructed without relying upon a priori information specifically relating RF coils with specific MR procedures. For example, the RF coil recommendation may be based on the type of MR procedure compared with the coil type (for example, a brain scan is suitably paired with a head RF coil while a chest scan is suitably paired with a torso coil; similarly, an MR procedure that is to use SENSE is suitably paired with a preformed multi-element coil array); MR system characteristics (for example, if the MR procedure is indicated to use certain RF receiver electronics, the RF coil is suitably selected to have a signal output that is compatible with the RF receiver electronics); and so forth.

The RF coils selection and preparation processor 92 provides an RF coil recommendation indicating one, two, three, or more RF coils that are recommended for the identified MR procedure 90. The recommendation is suitably displayed on the display 55 of the computer 54, and is additionally or alternatively optionally indicated using the set of LEDs 52 or other user-perceptible outputs. The human MR operator optionally has the option of accepting the RF coils recommendation as the selected coils for use in the identified MR procedure 90, or optionally can override the recommendations with respect to one or more of the recommended RF coils in making the final RF coils selection for the MR procedure 90.

Optionally, the RF coils selection and preparation processor 92 further invokes the coil update/configuration circuitry 80 to configure one or more of the RF coils selected for the identified MR procedure 90. For example, if a selected RF coil has a programmable signal output (for example, can output either wirelessly or via a fiber optical cable), then the RF coil is suitably configured by the coil configuration circuitry 80 of the RF coil docking station 30 to provide a signal output compatible with the electronics used in the identified MR procedure 90. Similarly, if the identified MR procedure 90 employs a tunable RF coil to detect non-¹H resonance, the coil configuration circuitry 80 of the RF coil docking station 30 suitably invokes the coil tuning circuitry 76 and network analyzer 44 to tune the RF coil to the requisite non-¹H resonance. Such coil configuration can be performed transparently to the human MR operator (optionally with notification of the updated coil configuration displayed on the display 55 of the computer 54), or optionally can be performed only after affirmative authorization by the human MR operator responsive to a display on the user interface 54 requesting such authorization.

Optionally, one or more of the RF coil receptacles may also act as an RF coil dispenser. For example, some types of RF coils may be expected to have relatively short useful lives, being considered as disposable consumables or being elements with short expected working lifetimes. For example, in a contagious environment it may be undesirable to place the same RF surface coil on successive imaging subjects, and accordingly the RF surface coil may be a disposable unit used for only a single subject. In other circumstances, the RF coil may be susceptible to damage due to RF exposure, or otherwise have a high likelihood of failure.

In such instances, the RF coil receptacle may include a drawer or other extended storage containing a plurality of RF coils of the same type. The user can then remove the RF coil that is at the front of the drawer or is otherwise made accessible to the user. In these embodiments, the stored coil detector 70 is suitably replaced by a stored coils counting mechanism that counts the number of stored coils in the drawer or other extended storage, and provides this information via the display 55 of the computer 54 or by another suitable human perceptible output. Alternatively, the stored coil detector 70 can be configured to detect whether there are any RF coils stored in the drawer or other extended storage, and operate the corresponding LED indicator 52, display a message on the display 55 of the computer 54, or otherwise notify the user when there are no remaining RF coils (thus indicating the RF coil receptacle needs to be reloaded with RF coils).

The invention has been described with reference to the preferred embodiments. Modifications and alterations may occur to others upon reading and understanding the preceding detailed description. It is intended that the invention be construed as including all such modifications and alterations insofar as they come within the scope of the appended claims or the equivalents thereof. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The disclosed embodiments can be implemented by means of hardware comprising several distinct elements, or by means of a combination of hardware and software. In the system claims enumerating several means, several of these means can be embodied by one and the same item of computer readable software or hardware. The mere fact that certain measures are recited in mutually different dependent claims does not indicate that a combination of these measures cannot be used to advantage.

1. An RF coil docking station comprising:
an RF coil receptacle configured to receive and store an RF coil and to convey data between the RE coil docking station and the stored RF coil; and
a processor configured to control conveyance of the data between the RF coil docking station and the stored RF coil to modify an operational state of the stored RF coil.

2. The RF coil docking station as set forth in claim 1, wherein the RF coil receptacle is configured to convey data between the RF coil docking station and the stored RF coil via at least one of:
(a) a wireless data communication connection,
(b) an electrically conductive data communication connection, and
(c) an optical fiber data communication connection.

3. The RF coil docking station as set forth in claim 1, wherein the RF coil receptacle is configured to convey data between the RF coil docking station and the stored RF coil via a same connection of the stored RF coil that is used to connect the RF coil with a magnetic resonance imaging system.

4. The RF coil docking station as set forth in claim 1, wherein the processor is configured to control conveyance of data between the RF coil docking station and the stored RF coil to convey a software update or firmware update to the stored RF coil.

5. The RF coil docking station as set forth in claim 4, wherein the RF coil docking station further comprises:
a digital data network connection configured to receive said software update or firmware update via the Internet.

6. The RF coil docking station as set forth in claim 1, further comprising:
a network analyzer configured to measure a radio frequency resonance characteristic of the stored RF coil, the processor being configured to control conveyance of data between the RF coil docking station and the stored RF coil to adjust the measured radio frequency resonance characteristic of the stored RF coil to a desired radio frequency resonance characteristic value.

7. The RF coil docking station as set forth in claim 1, further comprising:
a temperature sensor configured to measure a temperature, the processor being configured to control conveyance of data between the RF coil docking station and the stored RF coil to adjust a temperature-dependent operating parameter of the stored RF coil based on the measured temperature.

8. The RF coil docking station as set forth in claim 1 wherein the RF coil docking station includes a plurality of said RF coil receptacles configured to receive and store different RF coils and to convey data between the RF coil docking station and the different stored RF coils, the RF coil docking station further comprising:
a plurality of sensors configured to sense or detect selected characteristics of the stored RF coils including at least identity of the stored RF coils; and
one or more indicators configured to generate visually perceptible indications that are indicative of usability of the stored RF coils.

9. The RF coil docking station as set forth in claim 8, wherein the processor is further configured to (i) determine suitability of the stored RF coils for performing an identified magnetic resonance procedure and (ii) operate the one or more indicators to indicate suitability of the stored RF coils in the identified magnetic resonance procedure.

10. The RF coil docking station as set forth in claim 1 wherein the RE coil receptacle is configured as a dispenser storing a plurality of RF coils of the same type for dispensing, and the processor is configured to detect an RF coils occupancy status of said dispenser.

11. The RF coil docking station as set forth in claim 1, wherein the processor is configured to control conveyance of data between the RF coil docking station and the stored RF coil to perform a usability test of the stored RF coil, the RF coil docking station further comprising:
a sensor configured to sense or detect a result of the performed usability test; and
an indicator configured to generate a visually perceptible indication of usability of the stored RF coil based on the sensed or detected result of the performed usability test.

12. The RF coil docking station as set forth in claim 1, wherein the RF coil receptacle is configured as a dispenser storing a plurality of RF coils of the same type for dispensing, and the processor is configured to detect an RF coils occupancy status of said dispenser.

13. An RF coil docking method comprising:
storing an RF coil; and
during the storing, modifying an operational state of the stored RF coil.

14. The RF coil docking method as set forth in claim 13, wherein the modifying comprises:
conveying a software update or firmware update to the stored RF coil.

15. The RF coil docking method as set forth in claim 13 further comprising:
during the storing, measuring a radio frequency resonance characteristic of the stored RF coil, the modifying including adjusting the measured radio frequency resonance characteristic to a desired radio frequency resonance characteristic value.
